(19) United States
(12) Patent Application Publication
(10) Pub. No.: US 2026/0305192 A1
(43) Pub. Date: Oct. 1, 2026

(54) METHOD OF EPITAXIAL GROWTH AND METHOD OF MANUFACTURING SEMICONDUCTOR DEVICE USING THE SAME

(71) Applicant: RNR LAB INC., Yongin-si (KR)

(72) Inventors: Jeong Do RYU, Seoul (KR); Sung Ho KANG, Hwaseong-si (KR); Joo Hyun CHO, Yongin-si (KR); Sung Hoon RYU, Yangyang-gun (KR)

(73) Assignee: RNR LAB INC., Yongin-si (KR)

(21) Appl. No.: 19/630,688

(22) Filed: Mar. 27, 2026

(30) Foreign Application Priority Data
Mar. 28, 2025 (KR) 10-2025-0040209

(51) Int. Cl. H10P 14/24; H10P 14/60; H10P 34/42

(52) U.S. Cl. CPC H10P 14/24; H10P 14/6334; H10P 34/42

(57) ABSTRACT

An epitaxial growth method and a method for fabricating a semiconductor device applying the method are disclosed. The disclosed epitaxial growth method comprises the steps of preparing a base substrate; forming a semiconductor layer having a structure of one of an amorphous structure and a polycrystalline structure on the base substrate; forming an epitaxial layer having a crystalline structure by an epitaxial process on the semiconductor layer; and forming an insulating layer having a low thermal conductivity such that a temperature gradient characteristic appears on the epitaxial layer; heating at least one of the semiconductor layer and the epitaxial layer by irradiating the insulating layer with a laser to heat the insulating layer; and cooling the heated semiconductor layer to crystallize the semiconductor layer in accordance with the crystal structure of the epitaxial layer to form a crystallized epitaxial semiconductor layer from the semiconductor layer.

### CROSS-REFERENCES TO RELATED APPLICATION

The present application claims, under 35 U.S.C. § 119(a), the benefit of Korean Patent Application No. 10-2025-0040209, filed on Mar. 28, 2025 which is hereby incorporated by reference in its entirety.

### BACKGROUND

### 1. Field

The present disclosure relates to crystal growth technology, and more particularly to a method of epitaxial growth and a method of manufacturing a semiconductor device using the same.

### 2. Description of the Related Art

With the development of information and communication technology and the increasing demand for portable digital applications such as smartphones, digital cameras, and tablet PCs, the semiconductor market is expanding rapidly. Semiconductor technology has secured growth momentum in the semiconductor market by scaling down integrated circuits over the past few decades. However, it is becoming increasingly difficult to secure technological competitiveness through scaling down alone to achieve high density or high capacity. In recent years, research has been conducted to optimize performance while improving the density of devices through the development of materials for three-dimensionalization or high-performance realization of device shapes and the development of new manufacturing methods.

Various semiconductor materials are used to manufacture semiconductor devices, and depending on the composition and crystal structure of the material, the performance and characteristics of the device may vary significantly. In addition, the characteristics of the device may be greatly affected by the matching relationship or bonding characteristics between one material layer and another material layer in contact with it. In particular, improvement of semiconductor materials having a single crystal structure and the junction interface formed thereby may be advantageous in securing excellent performance. However, conventional methods for growing single-crystal semiconductors include high-temperature vapor deposition under certain conditions or molecular beam under vacuum, which have the limitation of requiring high-temperature processes with thermal burden on the lower layers or requiring vacuum processes. These high-temperature processes or vacuum processes require

Therefore, it is desirable to have a fabrication technique that may facilitate the formation of a semiconductor crystal layer with a single crystal structure having excellent electrical and optical properties under various conditions and environments. In particular, such a manufacturing technique may be advantageous for improving device performance and improving manufacturing economics.

### SUMMARY

The technical problem to be solved by the present disclosure is to provide an epitaxial growth method that may easily form a semiconductor crystal layer with a single crystal structure having excellent electrical and optical properties under various conditions and circumstances without heating the substrate to a high temperature or utilizing a vacuum.

Furthermore, a technical problem that the present disclosure seeks to solve is to provide a method for manufacturing a semiconductor device having excellent performance by applying the above-mentioned epitaxial growth method.

The problems to be solved by the present disclosure are not limited to those mentioned above, and other problems not mentioned will be clearly understood by those skilled in the art from the following description.

According to the present disclosure for accomplishing the above-mentioned tasks, a method of epitaxial growth comprising the steps of preparing a base substrate; forming a semiconductor layer having a structure of an amorphous structure or a polycrystalline structure on the base substrate; forming an epitaxial layer having a crystalline structure on the semiconductor layer by an epitaxial process; and forming an insulating layer having a low thermal conductivity on the epitaxial layer such that a temperature gradient is established from the insulating layer toward the semiconductor layer; heating at least one of the semiconductor layer and the epitaxial layer by irradiating the insulating layer with a laser; and by cooling the heated semiconductor layer to crystallize the semiconductor layer in accordance with the crystal structure of the epitaxial layer, forming an epitaxial semiconductor layer.

The thickness of the epitaxial layer has a range from 1 nm to 500 nm.

The epitaxial layer may comprise any one of silicon, silicon germanium, germanium, silicon carbide, GaAs, GaN, InGaAs, InAs, InP, AlGaN, and InSb.

The insulating layer has a thermal conductivity in the range of 0.01 to 20 W/(m.K).

The thickness of the insulating layer has a range from 1 micrometer to 10 micrometer.

The insulating layer may comprise a ceramic, an oxide ceramic, a nitride ceramic, a metal nitride or a combination thereof.

Before the step of forming the insulating layer, the method may further comprise the step of forming a metal layer on the epitaxial layer. During melting or cooling of the semiconductor layer, the temperature of the metal layer may be higher than the temperature of the insulating layer. The metal layer may comprise at least one of a metal and a metal compound, and the metal layer may comprise at least one of Ti, TiSi, Ta, Co, CoSi, Ni, NiSi, Ru, W, WSi, Cu, Re, Mo, Nb, and Cr. Wherein the metal layer has a thickness in the range of 5 nm to 10 micrometer.

Before the step of forming a metal layer on the epitaxial layer, the method may further comprise the step of forming a reaction inhibitor layer on the epitaxial layer. The reaction inhibiting layer has a thickness in the range of 0.5 nm to 50 nm. The reaction inhibitor layer may comprise at least one of Ti, TiN, W, WN, Ta, TaN, Si3N4, Nb, NbN.

The temperature gradient of the base substrate or the semiconductor layer is smaller than the temperature gradient of the epitaxial layer or the reaction suppression layer, the epitaxial layer exhibits a higher temperature gradient than the insulating layer and the metal layer, and the insulating layer or the metal layer exhibits a substantially linear temperature profile.

The method may further comprise the step of removing at least one of the reaction suppression layer, the metal layer and the insulating layer.

Wherein the laser has a wavelength in the range of 0.02 micrometer to 11 micrometer.

The present disclosure for achieving the above tasks, wherein the base substrate may comprise any one of monocrystalline silicon, monocrystalline silicon germanium, and monocrystalline germanium, and the semiconductor layer may comprise any one of silicon, silicon germanium, germanium, silicon carbide, GaAs, InGaAs, InAs, and InSb.

In accordance with other examples of the present disclosure to accomplish the above tasks, a method of manufacturing a semiconductor device may be provided, comprising: forming an epitaxial semiconductor layer using the above-described epitaxial growth method; and forming a semiconductor device having the epitaxial semiconductor layer.

According to another example of the present disclosure for accomplishing the above tasks, a semiconductor device comprising an epitaxial semiconductor layer formed by the aforementioned epitaxial growth method may be provided.

According to the present disclosure, it is possible to realize a method for forming an epitaxial semiconductor layer that may easily form a semiconductor layer with a single crystal structure having excellent properties under various conditions and circumstances without heating the substrate to a high temperature or utilizing a vacuum state. In particular, by utilizing the melting and temperature profile of the semiconductor layer according to the indirect heating method using a laser, the epitaxial semiconductor layer may be more easily formed in a way that is completely different from vapor deposition.

By applying the method of forming an epitaxial semiconductor layer according to the disclosure, semiconductor devices having excellent electrical and optical performance may be easily manufactured.

### BRIEF DESCRIPTION OF THE DRAWINGS

FIGS. 1A to 1E are cross-sectional views to illustrate an epitaxial growth method according to one example of the present disclosure.

FIGS. 2A to 2G are cross-sectional views to illustrate an epitaxial growth method according to another example of the present disclosure.

FIGS. 3A through 3H are cross-sectional views to illustrate an epitaxial growth method according to another example of the present disclosure.

FIG. 4 is a graph illustrating an exemplary result of evaluating the temperature profile of a sample surface upon cooling after laser irradiation in the formation process of an epitaxial semiconductor layer according to one example of the present disclosure.

FIG. 5 is a graph exemplarily showing the result of evaluating the temperature profile of a sample surface upon cooling after laser irradiation in the formation process of an epitaxial semiconductor layer according to another example of the present disclosure.

FIG. 6 is a graph exemplifying the results of evaluating the temperature profile of a sample surface upon cooling after laser irradiation in a process of forming an epitaxial semiconductor layer according to another example of the present disclosure.

FIG. 7 is a graph exemplarily showing the result of evaluating the temperature profile of a sample upon heating and cooling by laser irradiation in a process according to a comparative example.

### DETAILED DESCRIPTION

Hereinafter, the present disclosure will be described in detail with reference to the accompanying drawings.

The disclosure described below are provided to make the present disclosure more clear to those having ordinary knowledge in the art, and the scope of the present disclosure is not limited by the following examples, and the following examples may be modified in various other forms.

The terms used herein are intended to describe specific examples and are not intended to limit the present disclosure. Terms used herein in the singular form may include the plural form, unless the context clearly indicates otherwise. Furthermore, the terms “comprise” and/or “comprising” as used herein are intended to specify the presence of the mentioned shapes, steps, numbers, motions, absences, elements, and/or groups thereof, and are not intended to exclude the presence or addition of one or more other shapes, steps, numbers, motions, absences, elements, and/or groups thereof. Furthermore, as used herein, the term “connected” is intended to mean not only that certain elements are directly connected, but also that they are indirectly connected by the interposition of other elements between them.

Furthermore, when the present disclosure refers to a member being located “on” another member, this includes not only when a member is adjacent to another member, but also when there is another member between the two members. As used herein, the term “and/or” includes any one of the enumerated items and any combination of one or more of them. In addition, the terms “about,” “substantially,” and the like as used in the disclosure are intended to mean at or near the range of numbers or degrees, taking into account inherent manufacturing and material tolerances, and to prevent infringers from taking unfair advantage of the disclosure where precise or absolute numbers are stated, which are provided for the purpose of illustration.

The present disclosure will now be described in detail with reference to the accompanying drawings. The sizes or thicknesses of the areas or parts shown in the accompanying drawings may be somewhat exaggerated for clarity and ease of description. Throughout the detailed description, like reference numerals denote like components.

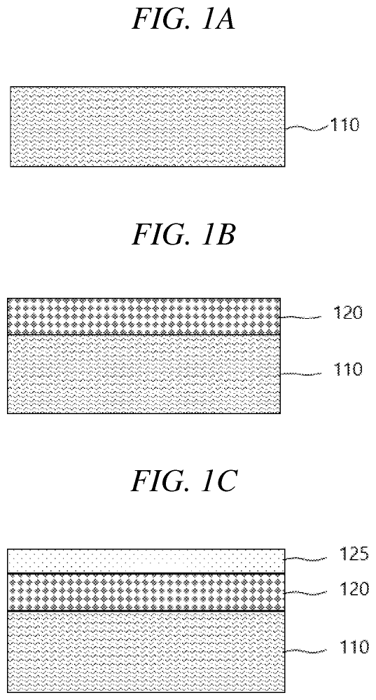

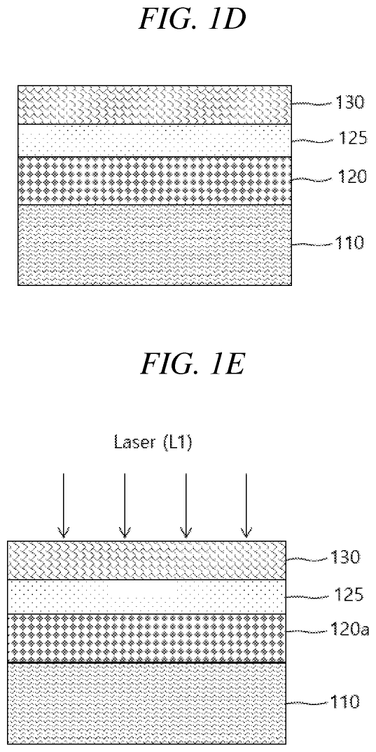

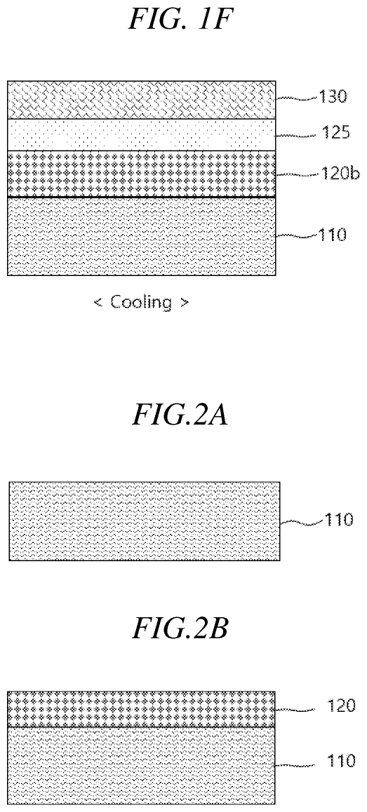

FIGS. 1A through 1E are cross-sectional views to illustrate an epitaxial growth method according to one example of the present disclosure.

Referring to FIG. 1A, a base substrate 110 may be prepared. The base substrate 110 may have a single crystal structure, wherein the single crystal structure may include any one of single crystal silicon (Si), single crystal silicon germanium (SiGe), and single crystal germanium (Ge). The base substrate 110 may be a single crystal substrate or a single crystal layer formed on the surface of a predetermined substrate or a three-dimensional shaped structure having a single crystal surface, and the present disclosure is not limited thereto. In FIG. 1A, a base substrate 110 of a single crystal structure having a flat surface that is part of a structure is illustrated. Non-limitingly, the base substrate 110 may be an amorphous substrate.

Referring to FIG. 1B, a semiconductor layer 120 having a structure of one of an amorphous structure and a polycrystalline structure is formed on the base substrate 110. Non-limitingly, the semiconductor layer 120 may be deposited on the base substrate 110 by any one of physical vapor deposition (PVD), chemical vapor deposition (CVD), and atomic layer deposition (ALD) methods. The semiconductor layer 120 may include, for example, a semiconductor based on the IV group, such as silicon (Si), silicon germanium (SiGe), germanium (Ge), silicon carbide (SiC), or a semiconductor based on the II-VI group, such as GaAs, InGaAs, InAs, or InSb, or a semiconductor based on the III-V group, such as GaAs, InGaAs, InAs, or InSb. The thickness of the semiconductor layer 120 may have a thickness in the range of, for example, 1 micrometer to 100 micrometer, but embodiments of the present disclosure are not limited thereto.

Referring to FIG. 1C, an epitaxial layer 125 may be formed on the semiconductor layer 120 via an epitaxial process. Non-limitingly, the epitaxial process may be performed by utilizing liquid phase epitaxy (LPE), molecular beam epitaxy (MBE), or vapor phase epitaxy (VPE). Alternatively, the epitaxial process may be performed via chemical vapor deposition (CVD) or physical vapor deposition (PVD). The epitaxial layer 125 may have homoepitaxy or heteroepitaxy, and may be a layer formed by the growth of crystals in a specific orientation. The epitaxial layer 125 may be used as a crystallization seed for crystallizing the semiconductor layer 120, which will be described later.

In one example, the epitaxial layer 125 has a thickness of 1 micrometer to 500 micrometer. If the epitaxial layer 125 has a thickness of 1 micrometer or less, only a portion of the semiconductor layer 120 may crystallize rather than all of the semiconductor layer 120, and if the epitaxial layer 125 has a thickness of 500 micrometer or more, the process time to form the epitaxial layer 125 may be long, which may make the process less economical and productive. Non-limitingly, the epitaxial layer 125 may include any of silicon, silicon germanium, germanium, silicon carbide, GaAs, GaN, InGaAs, InAs, InP, AlGaN, and InSb.

Referring to FIG. 1D, an insulating layer 130 having a low thermal conductivity may be formed on the epitaxial layer 125 to exhibit temperature gradient characteristics. Specifically, in the laser irradiation and cooling process to be described later, the base substrate 110 and the semiconductor layer 120 each exhibit a temperature gradient characteristic in which the temperature decreases from the top to the bottom due to the insulating layer 130 having a constant temperature curve. Non-limitingly, the insulating layer 130 may be deposited on the semiconductor layer 120 by any one of PVD, CVD, and ALD methods. The thermal conductivity of the insulating layer 130 may range from 0.01 to 20 W/(m.K), and the thickness of the insulating layer 130 may range from 1 micrometer to 10 micrometer. When a material having a thermal conductivity of 20 W/(m.K) or more is used, the thermal conductivity is not significantly different from the thermal conductivity of the underlying semiconductor layer or metal layer, so that when the heated or molten semiconductor layer 130 is cooled by heating the insulating layer 130 through laser irradiation, the temperature gradient characteristic does not appear or becomes worse, making it difficult to effectively have an epitaxial growth of the improved semiconductor layer 120. If the thickness of the insulating layer 130 is 10 micrometer or more, the amount of laser that penetrates the thickened insulating layer may be reduced, and the semiconductor layer that needs to be heated by laser irradiation due to the specific heat caused by the thicker thickness may not be effectively heated, and the heat treatment for single crystallization of the semiconductor layer 120 may not be effectively exhibited.

The insulating layer may comprise a ceramic, an oxide ceramic, a nitride ceramic, a metal nitride, or a combination thereof. The ceramic may comprise silicon (Si), the ceramic oxide may comprise silicon oxide (SiO2), the ceramic nitride may comprise silicon nitride (Si3N4), and the metal nitride may comprise any one of tungsten nitride (WN), tantalum nitride (TaN), titanium nitride (TiN), niobium nitride (NbN), and aluminum nitride (AlN). Preferably, the silicon (Si) has amorphous properties, and the silicon oxide (SiO2) and silicon nitride (Si3N4) have pores or amorphous properties.

Referring to FIG. 1E, by irradiating the insulating layer 130 with a laser L1 to heat the insulating layer 130, the semiconductor layer 120 and the epitaxial layer 125 may also be heated. At this time, the semiconductor layer 120 or the epitaxial layer 125 may be maintained at approximately the same high temperature because they are in contact with each other. However, since the semiconductor layer 120 has a relatively low melting point compared to the epitaxial layer 125, and the crystallized epitaxial layer 125 has a relatively high melting point compared to the semiconductor layer 120 having an amorphous or partially crystallized state, by appropriately adjusting the heating temperature, the semiconductor layer 120 may melt and become liquid, and the epitaxial layer 125 may remain solid.

For example, the semiconductor layer 120 may be heated or otherwise melted as the temperature of the semiconductor layer 120 is raised to about 1,000° C. to 1,600° C. Reference numeral 120a indicates a “heated semiconductor layer. The laser L1 intensity irradiated to the insulating layer 130 may be determined by considering the laser absorption rate or process conditions depending on the thickness, thermal conductivity, temperature gradient characteristics, and type of substrate of the insulating layer 130.

The laser L1 irradiating the insulating layer 130 may have a wavelength of about 0.02 micrometer to 11 micrometer. When at least one of these conditions is satisfied, the insulating layer 130 may be more easily heated using the laser L1, and by heating the insulating layer 130, the semiconductor layer 120 in contact with it may be more easily melted. On the other hand, the irradiation time of the laser L1 in the step of melting the semiconductor layer 120 may be from a few ps to tens of ms. However, the above range of irradiation times is exemplary and may vary in some cases.

In an example of the present disclosure, the insulating layer 130 is heated by irradiating the laser L1, and the base substrate 110 may not be melted while the semiconductor layer 120 and the epitaxial layer 125 are heated by the heating of the insulating layer 130. Therefore, a crystallization process for the semiconductor layer 120 may be performed without a high-temperature heating process, while maintaining the single crystal structure of the epitaxial layer 125. When heating the semiconductor layer 120 according to the heating method using the laser L1, an appropriate temperature profile may be applied in the thickness direction from the base substrate 110 to the insulating layer 130 by controlling the intensity of the irradiating laser L1. For example, during heating or cooling of the semiconductor layer 120, the temperature of the upper portion of the semiconductor layer 120 may be relatively high, and the temperature of the lower portion of the semiconductor layer 120 may be relatively low. The temperature of the upper portion of the base substrate 110 may be equal to the temperature of the lower portion of the semiconductor layer 120, and the temperature of the upper portion of the base substrate 110 may be relatively higher than the temperature of the lower portion of the base substrate 110. In this case, the insulating layer 130 has a temperature curve characterized by a nearly non-existent or nearly straight temperature gradient due to its low thermal conductivity, and is similar to the temperature on top of the semiconductor layer 120. The epitaxial layer 125 has a very low temperature gradient relative to the temperature gradient of the base substrate 110 or the semiconductor layer 120, and has a temperature curve characteristic similar to the insulating layer 130. In other words, the temperature of the upper portion of the heated semiconductor layer 120a may be relatively higher than the temperature of the lower portion thereof. And the temperature of the upper portion of the base substrate 110 may be relatively higher than the temperature of the lower portion thereof, but may be equal to the temperature of the lower portion of the semiconductor layer 120 and lower than the temperature of the upper portion of the semiconductor layer 120.

In the present disclosure, a temperature gradient refers to a change in temperature between the upper and lower portions, wherein a larger temperature gradient indicates a larger temperature difference between the upper and lower portions, and a smaller temperature gradient indicates a temperature difference between the upper and lower portions that is close to zero, i.e., a temperature gradient in the form of a straight line when there is no temperature difference between the upper and lower portions.

Referring to FIG. 1F, an epitaxial semiconductor layer 120b may be formed from the semiconductor layer 120a by heating or cooling the molten semiconductor layer 120a to single crystallize the semiconductor layer 120a according to the single crystal structure of the epitaxial layer 125. As the molten semiconductor layer 120a is cooled, crystallization may proceed along the lattice of the epitaxial layer 125, which may crystallize according to the single crystal structure of the epitaxial layer 125.

As a result, an epitaxial semiconductor layer 120b having a single crystal structure may be formed. If the epitaxial layer 125 is monocrystalline silicon and the semiconductor layer 120 is amorphous silicon, the epitaxial semiconductor layer 120b may be monocrystalline silicon, and no boundary may exist between the epitaxial layer 125 and the epitaxial semiconductor layer 20b. By way of non-limitation, if the semiconductor layer 20b according to the present disclosure is melted and crystallized according to the single crystal structure of the epitaxial layer 125, the method of forming the epitaxial semiconductor layer 120b may be referred to as a so-called liquid phase epitaxial (LPE) method. Such LPE growth methods may include laser (L1 in FIG. 1E) irradiation and appropriate temperature control.

Additionally, the cooling process of FIG. 1F may be a natural cooling process at room temperature or similar temperature conditions after laser (L1 of FIG. 1E) irradiation, but in some cases, the cooling process may be artificially controlled by controlling the temperature around the sample (i.e., the structure of FIG. 1F).

As described above, a semiconductor layer 120, an epitaxial layer 125, and an insulating layer 130 are sequentially deposited on the base substrate 110 to minimize heat loss by radiation and convection to the upper portion of the structure of FIG. 1F when cooling the sample (i.e., the structure of FIG. 1F) after the insulating layer 130 is laser annealed, a temperature gradient may be formed in the semiconductor layer 120, the epitaxial layer 125, and the insulating layer 130 on the base substrate 110 by conduction cooling through the lower portion of the structure of FIG. 1F.

In other examples, a metal layer 140 may be selectively deposited prior to forming the insulating layer 130 on the semiconductor layer 120.

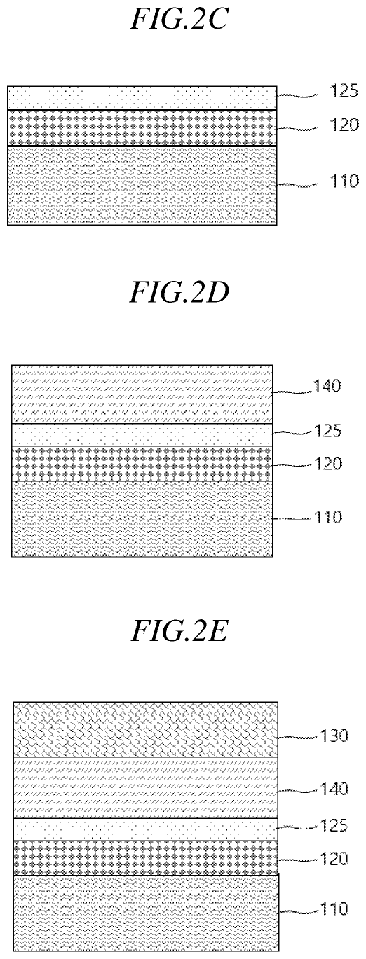

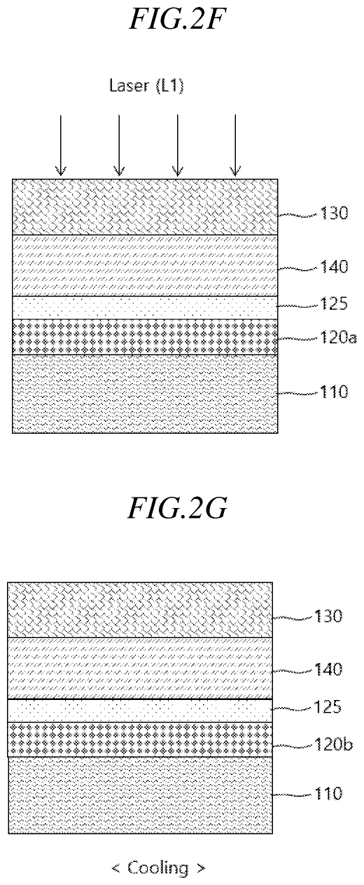

FIGS. 2A through 2F are cross-sectional views to illustrate epitaxial growth methods according to other examples of the present disclosure. Since FIGS. 2A and 2C are identical to FIGS. 1A and 1C, reference may be made to the description of FIGS. 1A and 1C unless contradictory.

Referring now to FIG. 2D, a metal layer 140 may optionally be formed on the epitaxial layer 125. Non-limitingly, the metal layer 140 may be deposited on the semiconductor layer 120 by any one of PVD, CVD, and ALD methods. The metal layer 140 may include at least one of a metal and a metal compound. For example, the metal layer 140 may include at least one of Ti, TiSi, Ta, Co, CoSi, Ni, NiSi, Ru, W, WSi, Cu, Re, Mo, Nb, and Cr. A larger thickness of the metal layer 140 enables higher temperatures to be realized with the same laser power, and preferably in the present disclosure, the metal layer 140 may have a thickness of 5 micrometer to 10 micrometer to improve its functionality, although the present examples are not limited thereto, and the suitable thickness of the metal layer 140 may be varied in some cases. The metal layer 140 may have a high absorption rate for the laser and may serve to absorb the laser to heat and melt the semiconductor layer 120, and may also serve as a capping layer that transmits heat to the semiconductor layer 120 and the epitaxial layer 125 or traps heat radiating from the heated semiconductor layer 120 and the epitaxial layer 125 toward the semiconductor layer 120 and the epitaxial layer 125. In this regard, the metal layer 140 may be referred to as a “laser absorber layer” or a “thermal capping layer” or a “heat transfer layer”. The metal layer 140 may have a higher melting point than the semiconductor layer 120, such that even if the semiconductor layer 120 is melted in a subsequent process, the metal layer 140 may not melt and maintain its structure (layer structure).

Then, referring to FIG. 2E, an insulating layer 130 may be formed on the metal layer 140. The insulating layer 130 is similar to the insulating layer 130 of FIG. 1D, so reference may be made to the description of FIG. 1D unless contradicted. Non-limitingly, the insulating layer 130 may be deposited on the metal layer 140 by any one of PVD, CVD, and ALD methods.

Then, referring to FIG. 2F, by irradiating the insulating layer 130 with the laser L1, the metal layer 140, which absorbs heat transferred through the insulating layer 130, may be heated. At this time, the metal layer 140 maintains a higher temperature than the insulating layer 130, and the semiconductor layer 120 and the epitaxial layer 125 may be heated through the heated metal layer 140. For example, when irradiated by a laser with the same power, the semiconductor layer 120 in FIG. 2F may be heated or melted at a higher temperature than in FIG. 1E. Therefore, adjustment of parameters such as laser intensity and irradiation time may be necessary to ensure that the semiconductor layer 120 of FIG. 1E and the semiconductor layer 120 of FIG. 2F are heated or melted in the same temperature environment. The insulating layer 130 deposited on the metal layer 140 may serve to protect the metal layer 140 while preventing deformations such as hillocks or pinholes generated by thermal stresses on the surface of the metal layer 140 during laser irradiation.

Referring to FIG. 2G, the heated or molten semiconductor layer 120a may be cooled to single crystallize the semiconductor layer 120a according to the single crystal structure of the epitaxial layer 125 to form a single crystallized epitaxial semiconductor layer 120b from the semiconductor layer 120a. As the heated or molten semiconductor layer 120a is cooled, crystallization may proceed along the lattice of the epitaxial layer 125, which may crystallize according to the single crystal structure of the epitaxial layer 125. As a result, an epitaxial semiconductor layer 120b having a single crystal structure may be formed. If the epitaxial layer 125 is monocrystalline silicon and the semiconductor layer 120 is amorphous silicon, the epitaxial semiconductor layer 120b may be monocrystalline silicon, and no boundary may exist between the epitaxial layer 125 and the epitaxial semiconductor layer 20b.

In the present disclosure, when the laser L1 irradiates the insulating layer 130, the metal layer 140 is heated through the heat absorbed from the insulating layer 130 heated by the laser, and the semiconductor layer 120 is heated and melted through the heated metal layer 140, the base substrate 110 and the epitaxial layer 125 may not be melted. Therefore, a crystallization process may be performed on the semiconductor layer 120 while maintaining the single crystal structure of the epitaxial layer 125 without a high temperature heating process. When melting the semiconductor layer 120 according to the heating method using the laser L1, an appropriate temperature profile may be applied in the thickness direction from the base substrate 110 to the insulating layer 130 by controlling the intensity of the irradiating laser L1. For example, during heating or cooling of the semiconductor layer 120, the temperature at the top of the semiconductor layer 120 may be relatively high, and the temperature at the bottom of the semiconductor layer 120 may be relatively low. The temperature of the upper portion of the base substrate 110 may be equal to the temperature of the lower portion of the semiconductor layer 120, and the temperature of the upper portion of the base substrate 110 may be relatively higher than the temperature of the lower portion of the base substrate 110. In this case, the insulating layer 130 has a temperature above the semiconductor layer 120 with a temperature gradient characteristic of almost no temperature gradient or a nearly straight temperature curve due to its low thermal conductivity. The metal layer 140 has a very low temperature gradient relative to the temperature gradient of the base substrate 110 or the semiconductor layer 120, and has a temperature curve characteristic similar to the insulating layer 130, with the temperature of the metal layer 140 being higher than the temperature of the insulating layer 130. The temperature below the epitaxial layer 125 is the same as the temperature above the semiconductor layer 120, and the temperature above the epitaxial layer 125 is the temperature of the metal layer 140, resulting in a temperature gradient that is relatively larger than the temperature gradient of the base substrate 110 or the semiconductor layer 120. By increasing the temperature gradient of the epitaxial layer 125, crystallization of the semiconductor layer 120 may be performed stably. In other words, the temperature of the upper part of the heated semiconductor layer 120a may be relatively higher than the temperature of the lower part, and at this time, the crystallization of the semiconductor layer 120 may be performed stably due to the epitaxial layer 125 having a relatively large temperature gradient. Due to this temperature gradient characteristic, epitaxial growth may be more effective than the epitaxial growth method of FIGS. 1A to 1E.

In another example, a reaction inhibitor layer 150 may optionally be added between the epitaxial layer 125 and the metal layer 140.

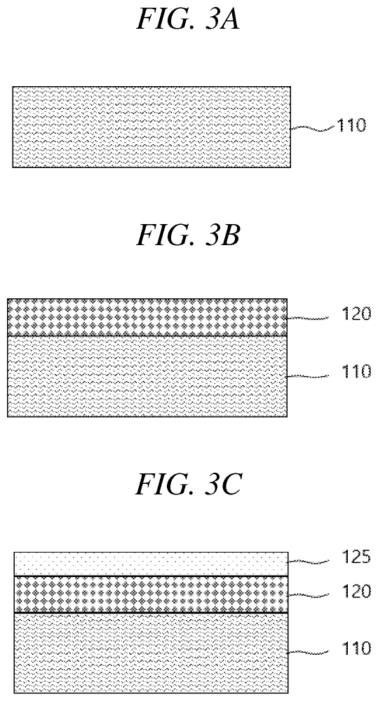

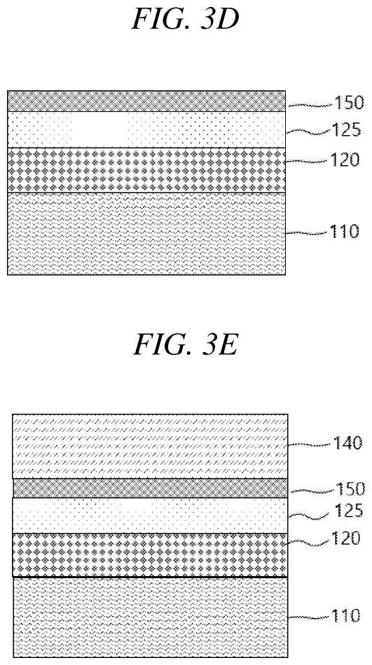

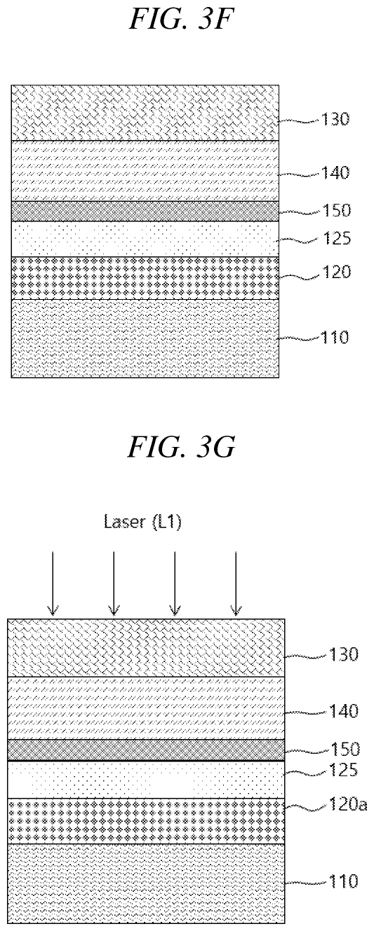

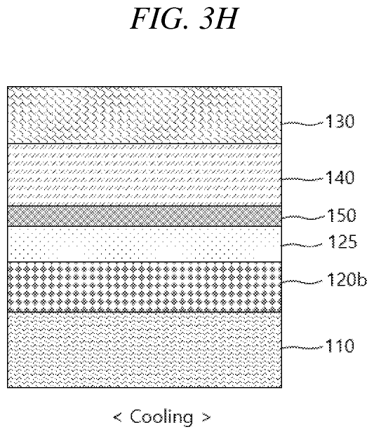

FIGS. 3A through 3H are cross-sectional views to illustrate epitaxial growth methods according to other examples of the present disclosure. Since FIGS. 3A to 3C are identical to FIGS. 1A to 1C, reference may be made to the description of FIGS. 1A to 1C unless contradictory.

Referring to FIG. 3D, prior to the step of forming the metal layer 140 on the epitaxial layer 125, a reaction inhibitor layer 150 may be formed on the epitaxial layer 125. Non-limitingly, the reaction inhibitor layer 150 may be deposited on the semiconductor layer 120 by any one of PVD, CVD, and ALD methods. By inhibiting chemical bonding or reaction between the metal layer 150 and the epitaxial layer 125 during the epitaxial growth process, the reaction inhibitor layer 150 may facilitate removal of the metal layer 150 after epitaxial growth without degradation.

The reaction inhibitor layer 150 has a thickness in the range of 0.5 micrometer to 50 micrometer. If the thickness of the reaction inhibitor layer 150 is 0.5 micrometer or less, it is difficult to effectively inhibit the chemical reaction between the metal layer 150 and the epitaxial layer 125, and if the thickness of the reaction inhibitor layer 150 is 50 micrometer or more, the semiconductor layer 120 may not be heated at a normal range of temperatures, resulting in no epitaxial growth of the semiconductor layer 120 or degradation of electrical or optical performance. The reaction inhibition layer may include at least one of Ti, TiN, W, WN, Ta, TaN, Si3N4, Nb, and NbN.

Next, a metal layer 140 may be formed on the reaction inhibition layer 150, as shown in FIG. 3E. The metal layer 140 is similar to the metal layer 140 of FIG. 2D, so reference may be made to the description of 2D unless contradicted.

Next, referring to FIG. 3F, an insulating layer 130 may be formed on the metal layer 140. The insulating layer 130 is similar to the insulating layer 130 of FIG. 1D, so reference may be made to the description of FIG. 1D unless contradicted.

Further, the laser irradiation of FIG. 3G and the conduction cooling of FIG. 3H are similar to FIGS. 2F and 2G, respectively, and reference may be made to the descriptions of FIGS. 2F and 2G unless contradictory. The conduction cooling is a technique for cooling an object by contacting it with a heat conductor.

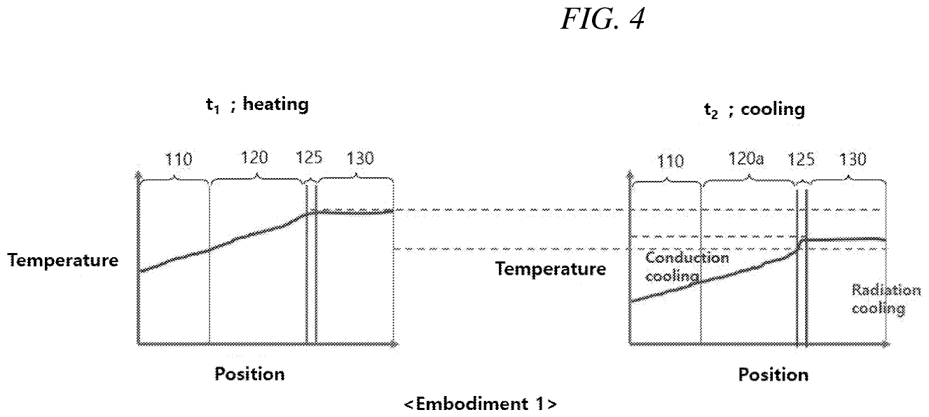

FIG. 4 is an exemplary graph showing the results of evaluating the temperature profile of a sample surface during cooling after laser irradiation in the formation process of an epitaxial semiconductor layer according to one example of the present disclosure. A sample according to this example comprises a base substrate 110, a semiconductor layer 120, an epitaxial layer 125, and an insulating layer 130, and a laser was irradiated to an open side of the insulating layer 130 to evaluate the temperature profile while heating the sample, and to evaluate the temperature profile while cooling after heating.

Referring to FIG. 4, it may be seen that the temperature of the insulating layer 130 has the highest and lowest temperature gradient characteristics during the heating stage, i.e., a temperature curve characterized by little difference between the lower and upper temperatures of the insulating layer 130. The epitaxial layer 125 in contact with the lower part of the insulating layer 130 is similar to the temperature of the insulating layer 130. In addition, the temperature of the interface where the semiconductor layer 120 and the epitaxial layer 125 are in contact is higher than the temperature of the interface where the semiconductor layer 120 and the base substrate 110 are in contact, and the temperature increases from the base substrate 110 to the semiconductor layer 120. In other words, the temperature of the upper part of the semiconductor layer 120 is higher than the temperature of the lower part of the semiconductor layer 120. Therefore, heating or melting may proceed from the upper part of the semiconductor layer 120 to the lower part of the semiconductor layer 120. Furthermore, the insulating layer 130 maintains a constant temperature due to its low thermal conductivity, i.e., the temperature of the lower part of the insulating layer 130 (e.g., the side in contact with the epitaxial layer 125) and the temperature of the upper part of the insulating layer 130 (the exposed side irradiated by the laser) are similar within a margin of error.

On the other hand, in the cooling step, radiation cooling may be performed on the surface portion of the insulating layer 130, and conduction cooling may be performed on the base substrate 110 side. While the insulating layer 130 maintains a constant temperature, a temperature decrease may be achieved, i.e., even if the temperature of the insulating layer 130 is decreased by radiation cooling, the temperature of the exposed surface of the insulating layer 130 and the temperature of the interface between the insulating layer 130 and the epitaxial layer 125 are approximately similar. As the heated or molten semiconductor layer 120a cools, crystallization may proceed along the lattice of the epitaxial layer 125. The upper temperature of the epitaxial layer 125 may follow the temperature of the insulating layer 130, and the lower temperature of the epitaxial layer 125 may follow the upper temperature of the semiconductor layer 120.

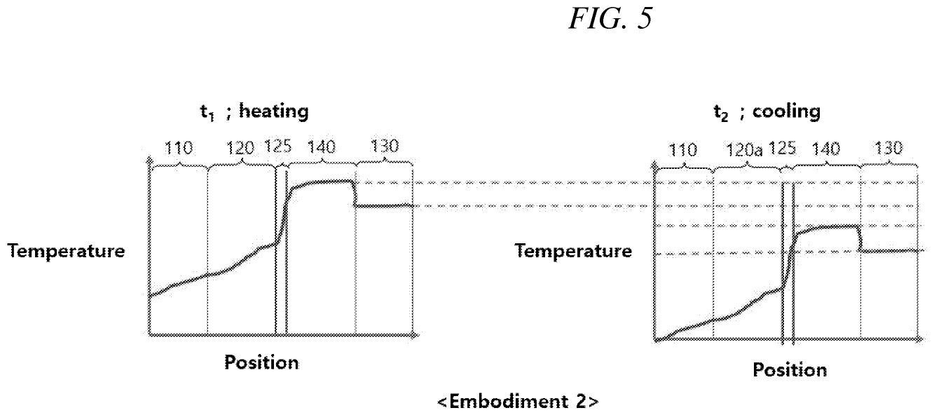

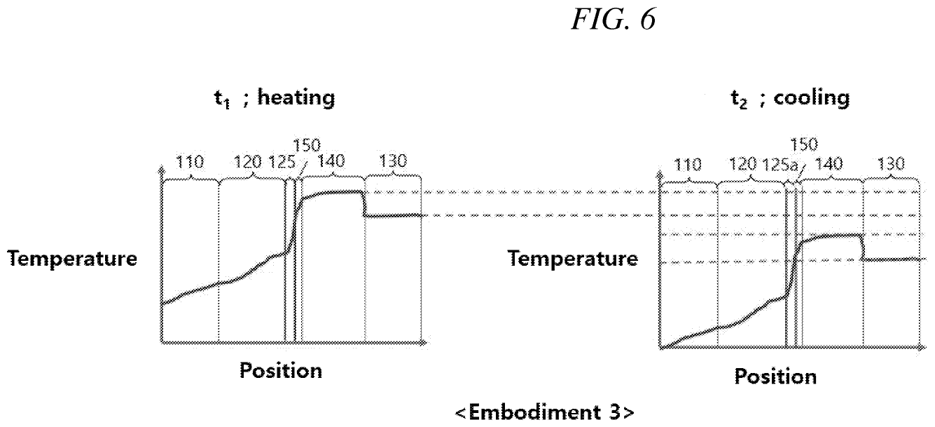

FIG. 5 is an exemplary graph showing the results of evaluating the temperature profile of a sample surface upon cooling after laser irradiation in the formation process of an epitaxial semiconductor layer according to another example of the present disclosure. A sample according to this disclosure comprises a base substrate 110, a semiconductor layer 120, an epitaxial layer 125, a metal layer 140, and an insulating layer 130, and a laser was irradiated to an open side of the insulating layer 130 to evaluate the temperature profile while heating the sample, and to evaluate the temperature profile while cooling after heating.

Referring to FIG. 5, it may be seen that the temperature of the metal layer 130 is the highest during the heating stage, and a straight line-shaped temperature curve characteristic appears for the metal layer 140 and the insulating layer 130, respectively. The temperature at the interface where the semiconductor layer 120 and the epitaxial layer 125 are in contact is higher than the temperature at the interface where the semiconductor layer 120 and the base substrate 110 are in contact, and the temperature increases from the base substrate 110 to the semiconductor layer 120. At this time, the interface between the metal layer 140 and the insulating layer 130 maintains a slightly higher temperature than the interface between the epitaxial layer 125 and the metal layer 140, and since the insulating layer 130 has a lower thermal conductivity characteristic than the metal layer 140, the temperature curve of the metal layer 140 is higher than the temperature curve of the insulating layer 130. The temperature of the upper part of the semiconductor layer 120 is higher than the temperature of the lower part of the semiconductor layer 120, which may cause heating or melting to proceed from the upper part of the semiconductor layer 120 to the lower part, and the metal layer 140 and the insulating layer 130 have different temperature curves, so that the upper part of the semiconductor layer 120 may be stably heated. Thus, the semiconductor layer 120 may be effectively epitaxially grown.

On the other hand, in the cooling step, radiation cooling may be performed on the surface of the insulating layer 130, and conduction cooling may be performed on the base substrate 110. The insulating layer 130 and the metal layer 140 may be cooled while maintaining a constant temperature. In this case, the temperature of the insulating layer 130 is lower than the temperature of the metal layer 140. As the heated or molten semiconductor layer 120a cools, crystallization may proceed along the lattice of the epitaxial layer 125.

FIG. 6 is an exemplary graph showing the results of evaluating the temperature profile of a sample surface upon cooling after laser irradiation in the formation process of an epitaxial semiconductor layer according to another example of the present disclosure. A sample according to this example comprises a base substrate 110, a semiconductor layer 120, an epitaxial layer 125, a reaction inhibitor layer 150, a metal layer 140, and an insulating layer 130, and a laser was irradiated to an open side of the insulating layer 130 to evaluate the temperature profile while heating the sample, and to evaluate the temperature profile while cooling after heating.

Referring to FIG. 6, it may be seen that the temperature profile of the sample in FIG. 5 appears similar to the temperature profile of the sample in FIG. 5, and that the reaction inhibitor layer 150 has a negligible effect on the temperature profile. For a description of the temperature profile of the sample in FIG. 6, reference may be made to the description of the temperature profile of the sample in FIG. 5. The reaction inhibitor layer 150 may inhibit chemical reactions between the metal layer 150 and the epitaxial layer 125 during the epitaxial growth process, and by minimizing chemical bonding or reactions between the metal layer 150 and the epitaxial layer 125, the metal layer 150 may be easily removed from the semiconductor layer 120 after epitaxial growth without degradation of electrical or optical performance.

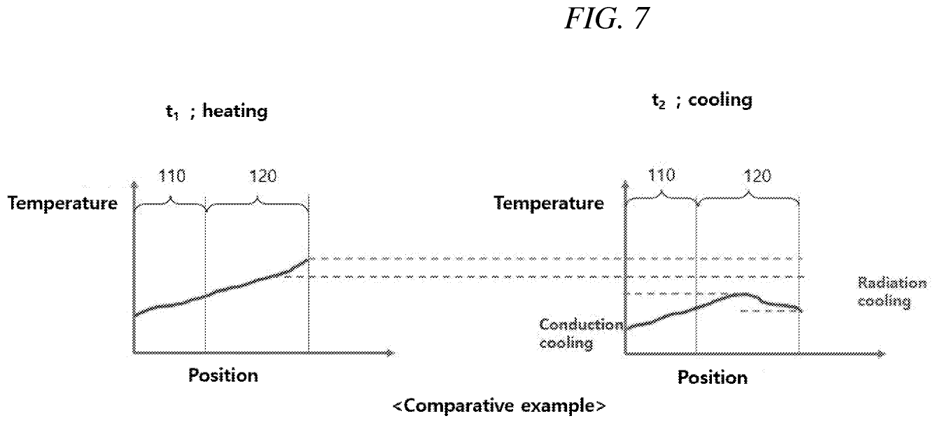

FIG. 7 is an exemplary graph showing the results of evaluating the temperature profile of a sample upon heating and cooling by laser irradiation in a process according to an exemplary example. The sample according to the comparative example comprises a base substrate 110, a semiconductor layer 120, and a laser was irradiated to an open side of the semiconductor layer 120 to evaluate the temperature profile while heating the sample, and to evaluate the temperature profile while cooling after heating.

Referring to FIG. 7, it may be seen that the temperature profiles upon heating and cooling in the sample according to a comparative example that does not use the metal layer 140 or the insulating layer 130 exhibit a significantly different behavior than the temperature profiles in the sample according to the example described with reference to FIGS. 4 through 6. Thus, when the epitaxial layer 125/insulating layer 130 or the epitaxial layer 125/insulating layer 130/metal layer 140 is used, the formation of the epitaxial semiconductor layer may be carried out reliably.

As described above, when the epitaxial layer 125 having a single crystal or polycrystalline crystal is formed on the semiconductor layer 120 and then laser heat treatment is performed, crystallization may be performed uniformly along the epitaxial crystal structure of the upper part of the semiconductor layer 120 in contact with the epitaxial layer 125 having a single crystal or polycrystalline crystal to the lower part of the semiconductor layer 120. On the other hand, when laser heat treatment is performed without the epitaxial layer 125, it may be difficult to achieve uniform crystallization in the thickness direction to the bottom of the semiconductor layer 120.

The epitaxial growth methods according to the present disclosure described above may be applied to the fabrication of various semiconductor devices. For example, the method of forming an epitaxial semiconductor layer according to the present disclosure may be applied instead of conventional vapor phase epitaxy or molecular beam epitaxy, and may be useful in situations or conditions where conventional vapor phase epitaxy or molecular beam epitaxy is difficult to apply. A method of manufacturing a semiconductor device according to the present disclosure may include the step of forming an epitaxial semiconductor layer by a method according to the above examples and the step of forming a semiconductor device having the epitaxial semiconductor layer.

Furthermore, according to the present disclosure, it is possible to implement a method of forming an epitaxial semiconductor layer that may facilitate the formation of a semiconductor layer with a single crystal structure having excellent properties under various conditions and circumstances without heating the substrate to a high temperature or utilizing a vacuum. In particular, by utilizing the melting and temperature profile of the semiconductor layer according to the indirect heating method using a laser, the epitaxial semiconductor layer may be more easily formed in a way that is completely different from vapor deposition. By applying the temperature profile according to the epitaxial growth method according to the above examples, semiconductor devices having excellent electrical and optical performance may be easily manufactured.

Preferred examples of the present disclosure have been disclosed herein, and although certain terms have been used, they are used in a general sense only to facilitate the description and understanding of the present disclosure and are not intended to limit the scope of the present disclosure. In addition to the present disclosure described herein, it will be apparent to those of ordinary skill in the art that other modifications based on the technical ideas of the present disclosure may be practiced. For example, one having ordinary knowledge in the art will recognize that the method of epitaxial growth and the method of fabricating semiconductor devices according to the examples described with reference to FIGS. 1A to 3H may be modified in various ways. The scope of the present disclosure is therefore not to be limited by the examples described, but by the technical ideas recited in the claims of the patent.

1. A method of epitaxial growth, comprising:
preparing a base substrate;
forming a semiconductor layer having an amorphous structure or a polycrystalline structure on the base substrate;
forming an epitaxial layer having a crystalline structure by an epitaxial process on the semiconductor layer;
forming an insulating layer having a low thermal conductivity on the epitaxial layer, such that a temperature gradient is established from the insulating layer toward the semiconductor layer;
heating at least one of the semiconductor layer and the epitaxial layer by irradiating the insulating layer with a laser; and
forming an epitaxial semiconductor layer by cooling the heated semiconductor layer to crystallize the semiconductor layer in accordance with a crystal structure of the epitaxial layer.

2. The method of claim 1, wherein the epitaxial layer has a thickness in the range of 1 nm to 500 nm.

3. The method of claim 1, wherein the epitaxial layer comprises any one of silicon, silicon germanium, germanium, silicon carbide, GaAs, GaN, InGaAs, InAs, InP, AlGaN, and InSb.

4. The method of claim 1, wherein the insulating layer has a thermal conductivity in the range of 0.01 to 20 W/(m.K).

5. The method of claim 1, wherein the thickness of the insulating layer has a range of 1 nm to 10 micrometer.

6. The method of claim 1, wherein the insulating layer is composed of a ceramic, an oxide ceramic, a nitride ceramic, a metal nitride, or a combination thereof.

7. The method of claim 1, further comprising: before the step of forming the insulating layer, forming a metal layer on the epitaxial layer.

8. The method of claim 7, wherein during heating or cooling of the semiconductor layer, a temperature of the metal layer is higher than a temperature of the insulating layer.

9. The method of claim 7, wherein the metallic layer comprises at least one of a metal and a metal compound, and
the metal layer comprises at least one of Ti, TiSi, Ta, Co, CoSi, Ni, NiSi, Ru, W, WSi, Cu, Re, Mo, Nb, and Cr.

10. The method of claim 7, wherein the metal layer has a thickness in the range of 5 nm to 10 micrometer.

11. The method of claim 7, further comprising: before the step of forming the metal layer on the epitaxial layer, forming a reaction inhibitor layer on the epitaxial layer.

12. The method of claim 11, wherein the reaction inhibitor layer has a thickness in the range of 0.5 nm to 50 nm.

13. The method of claim 11, wherein the reaction inhibitor layer comprises at least one of Ti, TiN, W, WN, Ta, TaN, Si₃N₄, Nb, and NbN.

14. The method of claim 11, wherein a temperature gradient of the base substrate or the semiconductor layer is smaller than a temperature gradient of the epitaxial layer or the reaction inhibitor layer,
the epitaxial layer exhibits a higher temperature gradient than the insulating layer and the metal layer, and
the insulating layer or the metal layer exhibits a substantially linear temperature profile.

15. The method of claim 11 further comprising: removing at least one of the reaction inhibitor layer, the metal layer, and the insulating layer.

16. The method of claim 1, wherein the laser has a wavelength in the range of 0.02 micrometer to 11 micrometer.

17. The method of claim 1, wherein the base substrate comprises any one of monocrystalline silicon, monocrystalline silicon germanium, and monocrystalline germanium, and
the semiconductor layer comprises any one of silicon, silicon germanium, germanium, silicon carbide, GaAs, InGaAs, InAs, and InSb.

18. A method of manufacturing a semiconductor device comprising:
forming an epitaxial semiconductor layer using the method of claim 1; and
forming a semiconductor device having the epitaxial semiconductor layer.

19. A semiconductor device comprising an epitaxial semiconductor layer formed by the epitaxial growth method of claim 1.
